(19) United States
(12) Patent Application Publication
(10) Pub. No.: US 2022/0018792 A1
(43) Pub. Date: Jan. 20, 2022

(54) OPTICAL DEVICES AND METHOD OF OPTICAL DEVICE METROLOGY

(71) Applicant: Applied Materials, Inc., Santa Clara, CA (US)

(72) Inventors: Sage Toko Garrett DOSHAY, Saratoga, CA (US); Rutger MEYER TIMMERMAN THIJSSEN, Sunnyvale, CA (US)

(21) Appl. No.: 17/360,715

(22) Filed: Jun. 28, 2021

Related U.S. Application Data
(60) Provisional application No. 63/054,033, filed on Jul. 20, 2020.

(51) Int. Cl. G01N 23/2251; G01N 21/956; H01J 37/28

(52) U.S. Cl. CPC G01N 23/2251; H01J 37/28; G01N 21/956

(57) ABSTRACT

Embodiments of the present disclosure relate to optical devices having one or more metrology features and a method of optical device metrology that provides for metrology tool location recognition with negligible impact to optical performance of the optical devices. The optical device includes one or more target features. The target features described herein provide for metrology tool location recognition with negligible impact to optical performance of the optical devices. In metrology processes, the target features allow for metrology tools to determine one or more locations of the optical device having a macroscale surface area. The target features correspond to one or more structures merged together, one or more structures merged together surrounded by one or more structures that have been removed, or one or more structures that have been removed having one or more profiles defined by adjacent structures to the target features.

### CROSS-REFERENCE TO RELATED APPLICATIONS

This application claims the benefit of U.S. Patent Application No. 63/054,033, filed on Jul. 20, 2020, the contents of which are herein incorporated by reference.

### BACKGROUND

### Field

Embodiments of the present disclosure generally relate to optical devices and a method of optical device metrology. More specifically, embodiments of the present disclosure relate to optical devices having one or more metrology features and a method of optical device metrology that provides for metrology tool location recognition with negligible impact to optical performance of the optical devices.

This application claims the benefit of U.S. Patent Application No. 63/054,033, filed on Jul. 20, 2020, the contents of which are herein incorporated by reference.

### Description of the Related Art

Optical devices may be used to manipulate the propagation of light. One example of an optical device is a flat optical device, such as a metasurface. Another example of an optical device is a waveguide combiner, such as an augmented reality waveguide combiner. Optical devices in the visible and near-infrared spectrum may require structures, such as nanostructures, disposed on a substrate surface having macroscale dimensions. The optical performance of the optical devices is dependent upon the characteristics of the nanostructures. The characteristics include the dimensions of the nanostructures as well as the location of the nanostructures with regard to other nanostructures.

Processing substrates to form optical devices is both complex and challenging as an emerging technology. In order to confirm that the nanostructures have dimensions within acceptable tolerances, metrology is needed to verify the dimensions. Accordingly, what is needed in the art are optical devices having one or more metrology features and a method of optical device metrology that provides for metrology tool location recognition with negligible impact to optical performance of the optical devices.

### SUMMARY

Embodiments of the present disclosure generally relate to optical devices and a method of optical device metrology. In one embodiment, an optical device includes a substrate and a plurality of structures disposed on a surface of the substrate of the optical device. The plurality of structures include critical dimensions less than one micron. The plurality of structures include one or more target features corresponding to one or more structures merged together. A ratio of one or more target features to the plurality of structures is between about 1:100,000 and about 1:1,000, 000,000.

In another embodiment, an optical device includes a substrate and a plurality of structures disposed on a surface of the substrate of the optical device. The plurality of structures include critical dimensions less than one micron. The plurality of structures include one or more target features. A ratio of one or more target features to the plurality of structures is between about 1:100,000 and about 1:1,000,000,000. The one or more target features are readable by metrology tools and include at least one or more structures merged together, one or more structures merged together surrounded by one or more structures that have been removed, or one or more structures that have been removed having one or more profiles defined by adjacent structures to the target features.

In yet another embodiment, a method includes directing a measurement area of a metrology tool over an approximate first location of a surface of a substrate of an optical device. The method further includes identifying a precise location of a first target feature of an optical device, the optical device including a plurality of structures disposed on the surface. The plurality of structures include one or more target features, wherein the one or more target features are readable by metrology tools and include at least one of one or more structures merged together, one or more structures merged together surrounded by one or more structures that have been removed, or one or more structures that have been removed having one or more profiles defined by adjacent structures to the target features. The method further includes determining one or more of critical dimensions, gaps, pitches, and peripheral distances of at least one of the plurality of structures based on the precise location within the measurement area. The method further includes repeating the steps of directing the measurement area of the metrology tool, identifying a target feature, and determining one or more of critical dimensions, gaps, pitches, and peripheral distances of at least one of the plurality of structures within the measurement area at one or more subsequent locations.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIGS. 1A, 1C, and 1E are schematic, top views of an optical device having one or more target features according to embodiments described herein.

FIGS. 1B, 1D, and 1F are schematic, cross-sectional views of an optical device having one or more target features according to embodiments described herein.

FIG. 2 is a flow diagram of a method for optical device metrology according to embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to optical devices and a method of optical device metrology. The metrology features of the optical devices described herein provide for metrology tool location recognition with negligible impact to on the optical performance of the optical devices. The metrology features allow for metrology tools to determine one or more locations of a portion of an optical device having a macroscale surface area.

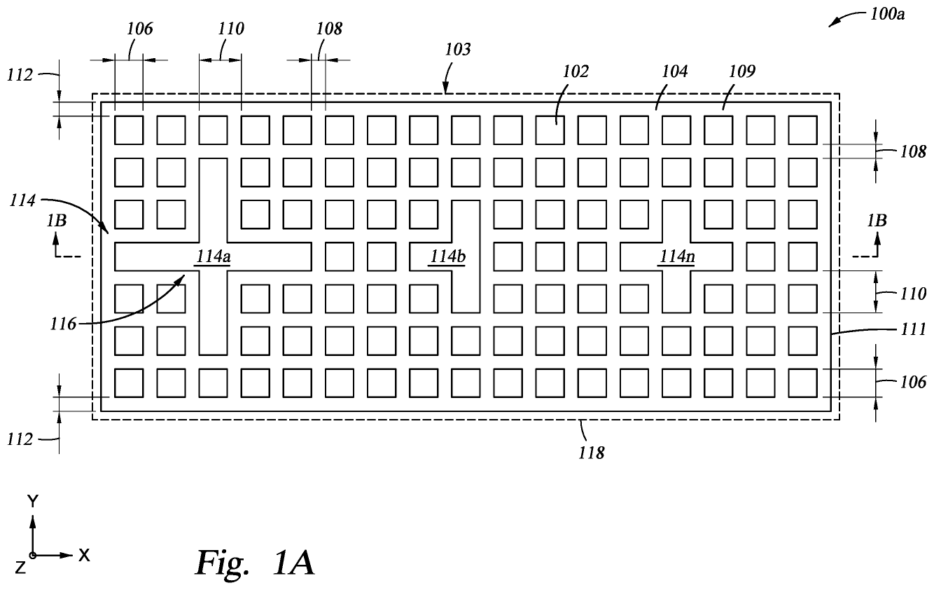

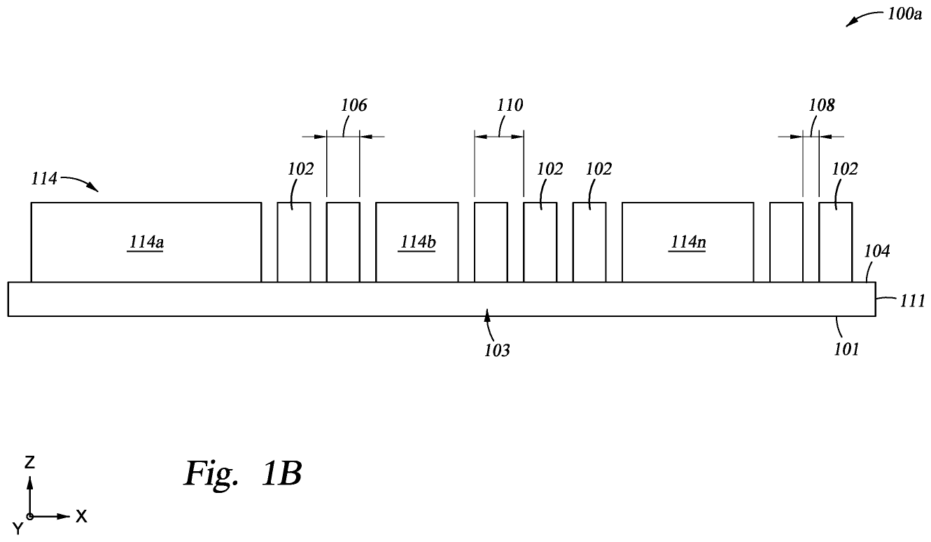

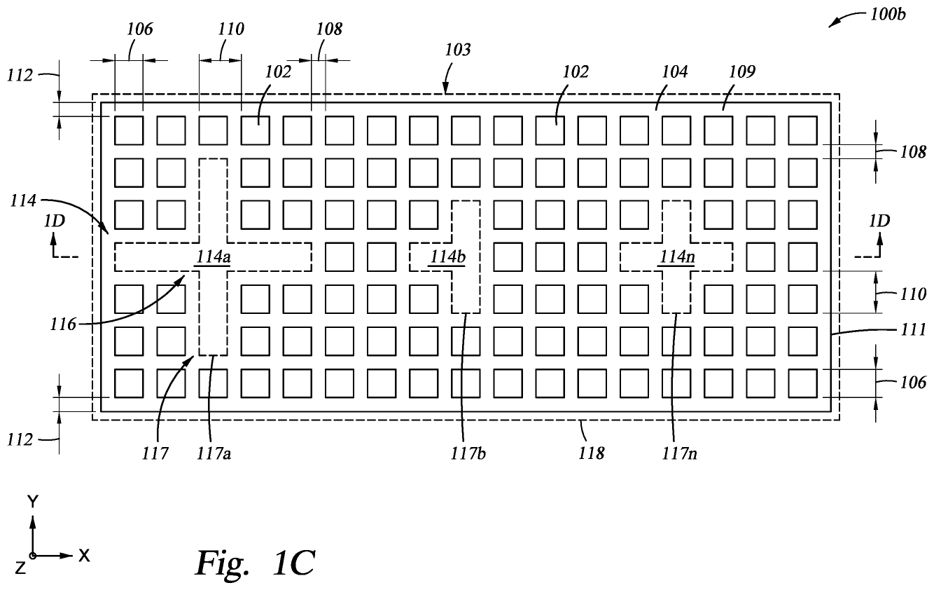

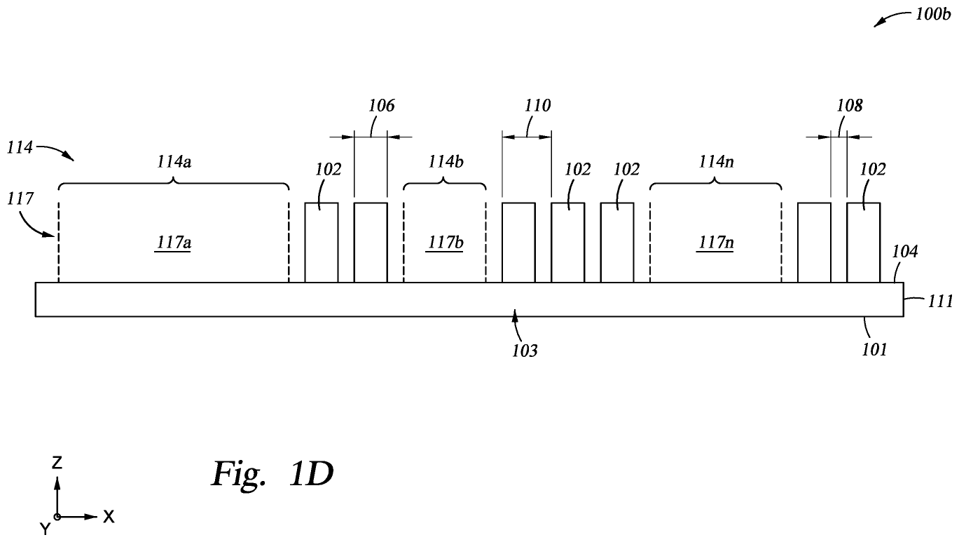

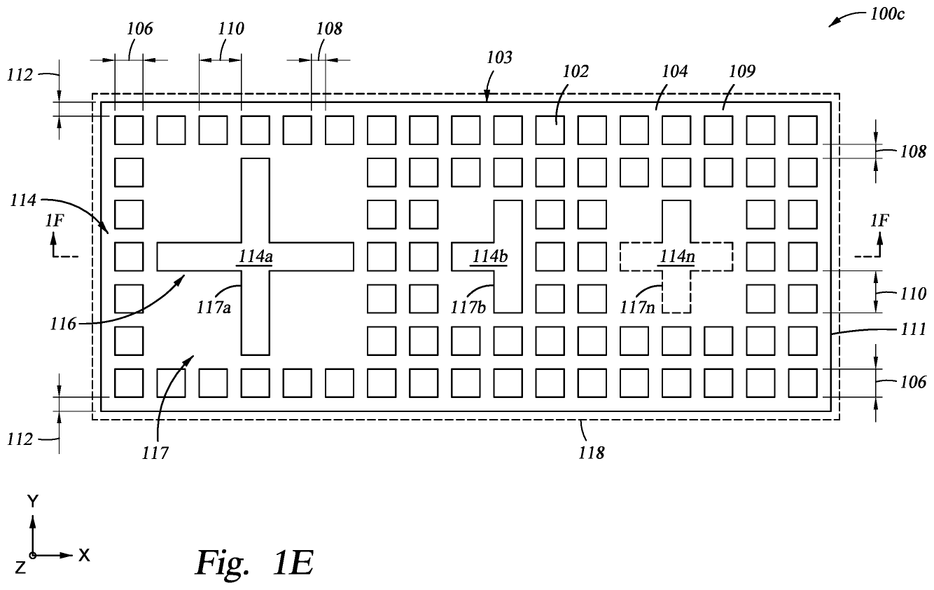

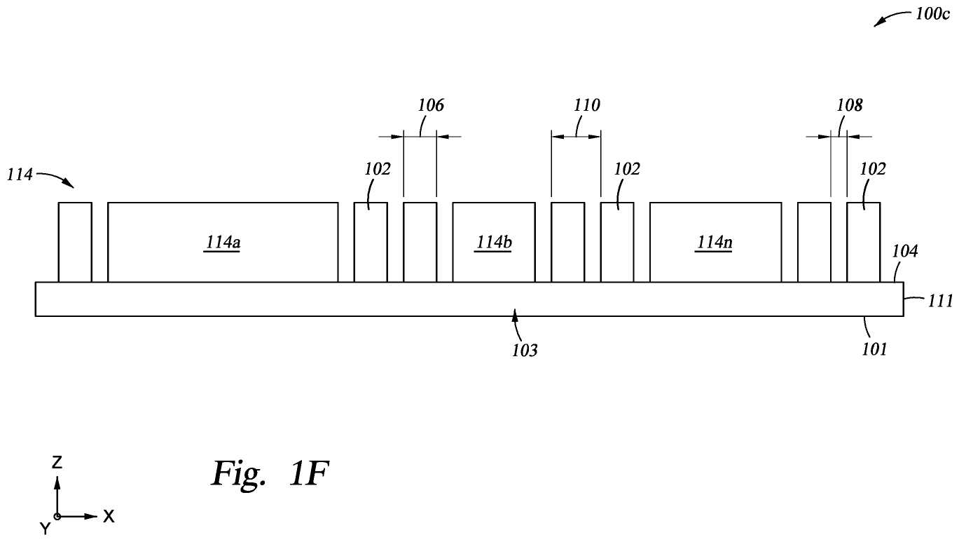

FIG. 1A is a schematic, top view, and FIG. 1B is a schematic, cross-sectional view of an optical device 100a having one or more target features 114 according to embodiments described herein. FIG. 1C is a schematic, top view, and FIG. 1D is a schematic, cross-sectional view of an optical device 100b having one or more target features 114 according to embodiments described herein. FIG. 1E is a schematic, top view, and FIG. 1F is a schematic, cross-sectional view of an optical device 100c having one or more target features 114 according to embodiments described herein.

Embodiments described herein provide for the optical devices 100a, 100b, and 100c that include structures 102 disposed on a surface 103 of a substrate 101. In some embodiments, which can be combined with other embodiments described herein, the optical devices 100a, 100b, and 100c are flat optical devices, such as metasurfaces. In other embodiments, which can be combined with other embodiments described herein, the optical devices 100a, 100b, and 100c are waveguide combiners, such as augmented reality waveguide combiners. In one embodiment, which can be combined with other embodiments described herein, a surface area 109 of the substrate 101 is about 70 cm² to about 800 cm². The surface 103 of the substrate 101 includes the structures 102, e.g., nanostructures, having dimensions less than one micron, e.g., nano-sized dimensions, disposed thereon. The structures 102 have critical dimensions 106, e.g., one of the width or diameter of the structures 102, the pitch of the structures 102, or the gap between the structures 102. In one embodiment, which may be combined with other embodiments described herein, the critical dimension 106 is less than 1 micrometer (μm) and corresponds to the width or diameter of the structures 102, depending on the cross-section of the structures 102. In one embodiment, which may be combined with other embodiments described herein, the critical dimensions 106 are about 100 nanometers (nm) to about 1000 nm. While FIGS. 1A-1F depict the structures 102 as having square or rectangular shaped cross-sections, the cross-sections of the structures 102 may have other shapes including, but not limited to, circular, triangular, elliptical, regular polygonal, irregular polygonal, and/or irregular shaped cross-sections. In some embodiments, which can be combined with other embodiments described herein, the cross-sections of the structures 102 on a single optical device 100a, 100b, 100c have different shapes.

The structures 102 of each of the optical devices 100a, 100b, and 100c include the critical dimensions 106. In some embodiments, which can be combined with other embodiments described herein, at least one of the critical dimensions 106 of a structure 102 may be different from at least one of the critical dimensions 106 of the one or more other structures 102. In some embodiments, which can be combined with other embodiments described herein, gaps 108 are disposed between each of the structures 102. In some embodiments, which can be combined with other embodiments described herein, the one or more of the gaps 108 surrounding a structure 102 are different from the one or more other gaps 108 surrounding another structure 102. In some embodiments, which can be combined with other embodiments described herein, the structures 102 may be arranged in one or more arrays 104. The one or more arrays 104 may be arranged aperiodically. In some embodiments, which can be combined with other embodiments described herein, the structures 102 are arranged in two or more arrays 104. In the embodiments, which can be combined with other embodiments described herein, each of the structures 102 may have pitches 110, i.e., the distance between leading edges of adjacent structures 102. In one embodiment, which may be combined with other embodiments described herein, the pitches 110 in an X direction are different than the pitches 110 in a Y direction. In another embodiment, which may be combined with other embodiments described herein, one or more pitches 110 in the X direction are different than one or more other pitches 110 in the X direction, and/or one or more pitches 110 in the Y direction are different than one or more other pitches 110 in the Y direction. In some embodiments, which can be combined with other embodiments described herein, the structures 102 adjacent to one of the edges 111 of the surface 103 may have peripheral distances 112, i.e., the distance from structures 102 to one of the edges 111 immediately adjacent thereto. In one embodiment, which may be combined with other embodiments described herein, at least one of the peripheral distances 112 may be different than the other peripheral distances 112.

The plurality of structures 102 include one or more target features 114a, 114b, . . . 114n (collectively referred to herein as “target features 114”). In one embodiment, which may be combined with other embodiments described herein, the target features 114 correspond to one or more structures 102 merged together. In another embodiment, which may be combined with other embodiments described herein, the target features 114 correspond to one or more structures 102 merged together surrounded by one or more structures 102 that have been removed. In yet another embodiment, which may be combined with other embodiments described herein, the target features 114 correspond to one or more structures 102 that have been removed having one or more profiles defined by adjacent structures 102 to the target features 114. The target features 114 described herein provide for metrology tool location recognition and result in negligible impact to optical performance of the optical devices 100a, 100b, and 100c. For example, the optical devices 100a, 100b, and 100c have a ratio of structures 102 merged together, structures 102 that have been removed, or a combination of both to total structures 102 of about 1:100,000 to about 1:1,000,000,000.

In metrology processes, such as the method 200 described herein, the target features 114 allow for metrology tools to determine one or more locations 116 of the surface 103, e.g. a surface 103 having a macroscale surface area 109. From the one or more locations 116, metrology tools, such as any electron-beam-based metrology tool, including, but not limited to, a Scanning Electron Microscope (SEM), a Critical Dimension Scanning Electron Microscope (CDSEM), or a Transmission Electron Microscope (TEM), are able to measure one or more of the critical dimensions 106, the gaps 108, the pitches 110, peripheral distances 112, and other dimensions within a measurement area 118 of the metrology tools. In one embodiment, which may be combined with other embodiments described herein, the measurement area 118 is less than about 40 micrometers (μm). The one or more the target features 114 are readable by metrology tools. The one or more the target features 114 allow for one or more of the critical dimensions 106, the gaps 108, the pitches 110, peripheral distances 112, and other dimensions of each of the one or more structures 102 disposed on the surface 103 having macroscale dimensions to be measured by the metrology tools.

As shown in FIGS. 1A and 1B, the target features 114 may correspond to one or more structures 102 merged together. In the embodiments of FIGS. 1A and 1B, which can be combined with other embodiments described herein, the target features 114 include, but are not limited to, cross (shown in FIGS. 1A and 1B), rectangular, square, circular, semicircular, triangular, and/or other patterns readable by the metrology tools, such as any electron-beam-based metrology tool, including, but not limited to, a SEM, a CDSEM, or a TEM. As shown in FIGS. 1C and 1D, the target features 114 may correspond to one or more structures 102 that have been removed. In the embodiments of FIGS. 1C and 1D, which can be combined with other embodiments described herein, the target features 114 have one or more profiles 117a, 117b, . . . 117n (collectively referred to herein as “profiles 117”) defined by the structures 102 of the optical device 100b adjacent to the structures 102 that have been removed. The profiles 117 include, but are not limited to, cross (shown in FIGS. 1C and 1D), rectangular, square, circular, semicircular, triangular, and/or other patterns readable by the metrology tools, such as any electron-beam-based metrology tool, including, but not limited to, a SEM, a CDSEM, or a TEM. As shown in FIGS. 1E and 1F, the target features 114 may correspond to one or more structures 102 merged together surrounded by the one or more structures 102 that have been removed. In the embodiments of FIGS. 1E and 1F, which can be combined with other embodiments described herein, the target features 114 include, but are not limited to, cross (shown in FIGS. 1E and 1F), rectangular, square, circular, semicircular, triangular, and/or other patterns readable by the metrology tools, such as any electron-beam-based metrology tool, including, but not limited to, SEM, CDSEM, or a TEM.

In one embodiment, which may be combined with other embodiments described herein, the structures 102 are formed of substrate material. In another embodiment, which can be combined with other embodiments described herein, the structures 102 include one or more structure materials. In one embodiment, which may be combined with other embodiments described herein, the one or more target features 114 are formed of substrate material. In another embodiment, which can be combined with other embodiments described herein, the target features 114 include one or more structure materials. In another embodiment, which may be combined with other embodiments described herein, the structures 102 and the target features 114 include the same materials. In yet another embodiment, which may be combined with other embodiments described herein, the structures 102 and the target features 114 include different materials.

The substrate 101 may also be selected to transmit a suitable amount of light of a desired wavelength or wavelength range, such as one or more wavelengths from about 100 to about 3000 nanometers. Without limitation, in some embodiments, the substrate 101 is configured such that the substrate 101 transmits greater than or equal to about 50% to about 100%, of an infrared to ultraviolet region of the light spectrum. The substrate 101 may be formed from any suitable material, provided that the substrate 101 can adequately transmit light in a desired wavelength or wavelength range and can serve as an adequate support for the optical devices 100a, 100b, 100c described herein. In some embodiments, which can be combined with other embodiments described herein, the material of substrate 101 has a refractive index that is relatively low, as compared to the refractive index of the structure material of the plurality of structures 102. Substrate selection may include substrates of any suitable material, including, but not limited to, amorphous dielectrics, non-amorphous dielectrics, crystalline dielectrics, silicon oxide, polymers, and combinations thereof. In some embodiments, which may be combined with other embodiments described herein, the substrate 101 includes a transparent material. In one embodiment, which may be combined with other embodiments described herein, the substrate 101 is transparent with an absorption coefficient smaller than 0.001. Suitable examples may include an oxide, sulfide, phosphide, telluride or combinations thereof. In one example, the substrate 101 includes silicon (Si), silicon dioxide (SiO₂), silicon nitride (SiN), fused silica, quartz, silicon carbide (SiC), germanium (Ge), silicon germanium (SiGe), indium phosphide (InP), gallium arsenide (GaAs), gallium nitride (GaN), sapphire, high-index transparent materials such as high-refractive-index glass, or combinations thereof.

In one embodiment, which may be combined with other embodiments described herein, the structure material of the structures 102 and/or the target features 114 include non-conductive materials, such as dielectric materials. The dielectric materials may include amorphous dielectrics, non-amorphous dielectrics, and crystalline dielectrics. Examples of the dielectric materials include, but are not limited to, silicon-containing materials, such as Si, silicon nitride (Si₃N₄), silicon oxynitride, and silicon dioxide. The silicon may be crystalline silicon, polycrystalline silicon, and/or amorphous silicon (a-Si). In another embodiment, which may be combined with other embodiments described herein, the structure material of the structures 102 and/or target features 114 include metal-containing dielectric materials. Examples of metal-containing dielectric materials include, but are not limited to, titanium dioxide (TiO₂), zinc oxide (ZnO), tin dioxide (SnO₂), aluminum-doped zinc oxide (AZO), fluorine-doped tin oxide (FTO), cadmium stannate (Cd₂SnO₄), cadmium stannate (tin oxide) (CTO), zinc stannate (SnZnO₃), and niobium oxide (Nb₂O₅) containing materials. In yet another embodiment, which can be combined with other embodiments described herein, the structure material of the structures and/or target features 114 include nanoim print resist materials. Examples of nanoimprint resist materials include, but are not limited to, at least one of spin on glass (SOG), flowable SOG, organic, inorganic, and hybrid (organic and inorganic) nanoimprintable materials that may contain at least one of silicon oxycarbide (SiOC), titanium dioxide (TiO₂), silicon dioxide (SiO₂), vanadium (IV) oxide (VOX), aluminum oxide (Al₂O₃), indium tin oxide (ITO), zinc oxide (ZnO), tantalum pentoxide (Ta₂O₅), silicon nitride (Si₃N₄), titanium nitride (TiN), and zirconium dioxide (ZrO₂) containing materials, or combinations thereof.

In one embodiment, which may be combined with other embodiments described herein, the structures 102 and the target features 114 may be formed by one of ion-beam etching, reactive ion etching, electron-beam (e-beam) etching, wet etching, nanoimprint lithography (NIL), and combinations thereof. In another embodiment, which can be combined with other embodiments described herein, a resist is disposed over one of a structure material layer and the surface 103 of the substrate 101. In another embodiment, which can be combined with other embodiments described herein, a NIL process is used to directly pattern the structure material layer. In one embodiment, which may be combined with other embodiments described herein, the resist is exposed in a lithography process and developed to expose unmasked portions of a hardmask disposed between one of the structure material layer and the surface 103 and the resist. In another embodiment, which can be combined with other embodiments described herein, the resist is imprinted in a NIL process to expose unmasked portions of the hardmask disposed between one of the structure material layer and the surface 103 and the photoresist. The unmasked portions of the hardmask are etched to expose one of the structure material layer and the surface 103. The exposed structure material layer or surface 103 is etched to form the structures 102 and target features 114. In the embodiments described herein, which can be combined with other embodiments described herein, the exposed structure material layer or surface 103 is etched by ion-beam etching or e-beam etching. In some embodiments, which can be combined with other embodiments described herein, the hardmask is removed after the exposed structure material layer or surface 103 is etched.

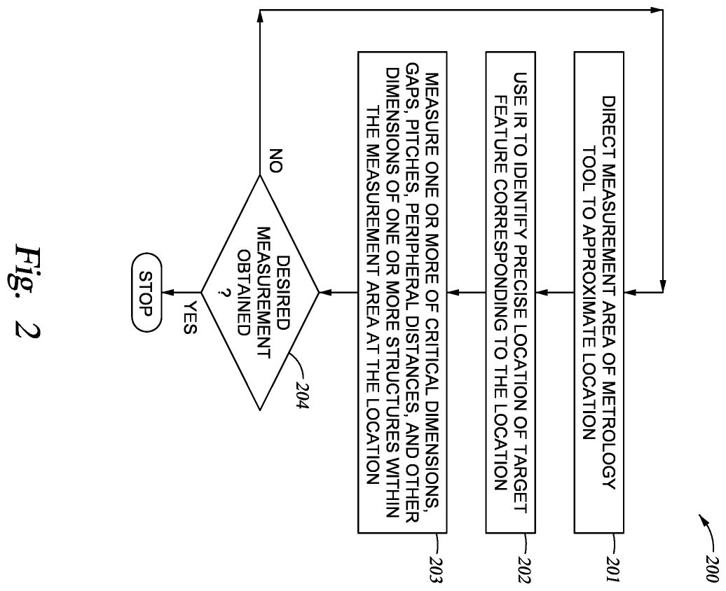

FIG. 2 is a flow diagram of a method 200 for optical device metrology. The method 200 provides for the determination of one or more of the critical dimensions 106, the gaps 108, the pitches 110, peripheral distances 112, and other dimensions of each of the one or more structures 102 of an optical device 100a, 100b, 100c. The method 200 utilizes a metrology tool, such as a CDSEM, operable to direct a measurement area 118 (e.g., a imaging area) to the one or more locations 116, read the one or more the target features 114, and measure one or more of the critical dimensions 106, the gaps 108, the pitches 110, the peripheral distances 112, and other dimensions of each of the one or more structures 102 based on instructions associated with respective features 114 as described herein.

At operation 201, the metrology tool directs the measurement area 118 to a first location 116a of the one or more locations 116 within an approximate region. At operation 202, once the metrology tool directs the measurement area 118 to the approximate region of the first location 116a, the metrology tool identifies a precise location of a first target feature 114a of the optical device 100a, 100b, 100c. In one embodiment, which may be combined with other embodiments described herein, the precise location of the first target feature 114a is within about 40 μm of the first location 116a. In one embodiment, which may be combined with other embodiments described herein, the metrology tool uses Image Recognition (IR) software to identify a precise location of a first target feature 114a of the optical device 100a, 100b, 100c. At operation 203, the metrology tool measures one or more of the critical dimensions 106, the gaps 108, the pitches 110, the peripheral distances 112, and other dimensions of one or more structures 102 at a specified location relative to the first target feature 114a and within the measurement area 118 of the first location 116a based on instructions associated with the first location 116a. In one embodiment, which may be combined with other embodiments described herein, the metrology tool is operable to store instructions to determine one or more of the critical dimensions 106, the gaps 108, the pitches 110, the peripheral distances 112, and other dimensions of one or more structures 102 when the metrology tool moves to the measurement area 118 relative to the precise location of the first target feature 114a.

At optional operation 204, operations 201 and 202 are repeated for subsequent target features 114b, . . . 114n. Operations 201, 202, and 203 may be repeated after locating the subsequent target features 114b, . . . 114n until desired measurements of the one or more of the critical dimensions 106, the gaps 108, the pitches 110, the peripheral distances 112, and other dimensions of one or more structures 102 are obtained by the metrology tool. In one embodiment, which may be combined with other embodiments described herein, the metrology tool is operable to store instructions to determine one or more of the critical dimensions 106, the gaps 108, the pitches 110, the peripheral distances 112, and other dimensions of one or more structures 102 when the metrology tool moves to the measurement area 118 relative to the precise location of the subsequent target feature 114b. In another embodiment, which can be combined with other embodiments described herein, the metrology tool is operable to store instructions to determine one or more of the critical dimensions 106, the gaps 108, the pitches 110, the peripheral distances 112, and other dimensions of one or more structures 102 when the subsequent target feature 114n is read or identified by the metrology tool.

In summation, optical devices 100a, 100b, 100c having one or more target features 114 and a method of optical device metrology are provided. The target features 114 described herein provide for metrology tool location recognition with negligible impact to optical performance of the optical devices 100a, 100b, 100c. In metrology processes, such as the method 200 described herein, the target features 114 allow for metrology tools to determine one or more locations 116 of the surface 103 having a macroscale surface area 109. At the one or more locations 116, metrology tools, such as a CDSEM, are able to reliably and precisely measure one or more of the critical dimensions 106, the gaps 108, the pitches 110, peripheral distances 112, and other dimensions of one or more structures 102 disposed on the surface 103.

While the foregoing is directed to embodiments of the present disclosure, other and further embodiments of the disclosure may be devised without departing from the basic scope thereof, and the scope thereof is determined by the claims that follow.

1. An optical device, comprising:
a substrate; and
a plurality of structures disposed on a surface of the substrate of the optical device, the plurality of structures having critical dimensions less than one micron, the plurality of structures including one or more target features corresponding to one or more structures merged together, wherein a ratio of one or more target features to the plurality of structures is between about 1:100,000 and about 1:1,000,000,000.

2. The optical device of claim 1, wherein the one or more target features are readable by metrology tools.

3. The optical device of claim 2, wherein the metrology tools include a Scanning Electron Microscope (SEM), Critical Dimension Scanning Electron Microscope (CDSEM), or a Transmission Electron Microscope (TEM).

4. The optical device of claim 3, wherein the structures merged together include cross, rectangular, square, circular, semicircular, triangular, and/or other patterns readable by the metrology tools.

5. The optical device of claim 3, wherein the one or more target features correspond to one or more structures of the plurality of structures merged together surrounded by one or more structures of the plurality of structures that have been removed.

6. The optical device of claim 3, wherein the one or more target features correspond to one or more structures of the plurality of structures that have been removed having one or more profiles defined by adjacent structures to the target features.

7. The optical device of claim 6, wherein the one or more profiles include cross, rectangular, square, circular, semicircular, triangular, and/or other patterns readable by the metrology tools.

8. The optical device of claim 1, wherein the plurality of structures includes structures comprising:
widths or diameters corresponding to critical dimensions of the plurality of structures;
gaps between each of the structures; and
pitches corresponding to distances between leading edges of adjacent structures of the plurality of structures.

9. The optical device of claim 8, wherein the plurality of structures are arranged in two or more arrays.

10. The optical device of claim 9, wherein at least one of the critical dimensions or the pitches of the plurality of structures of a first array are different than the critical dimensions or pitches of the plurality of structures of a second array.

11. The optical device of claim 8, wherein the plurality of structures are arranged in one or more arrays, and the one or more arrays are arranged aperiodically.

12. The optical device of claim 8, wherein the critical dimensions of the plurality of structures are less than 1 micrometer (μm).

13. An optical device, comprising:
a substrate; and
a plurality of structures disposed on a surface of the substrate of the optical device, the plurality of structures having critical dimensions less than one micron, the plurality of structures including one or more target features, wherein a ratio of one or more target features to the plurality of structures is between about 1:100,000 and about 1:1,000,000,000, the one or more target features are readable by metrology tools and include at least one of:
one or more structures merged together;
one or more structures merged together surrounded by one or more structures that have been removed; or
one or more structures that have been removed having one or more profiles defined by adjacent structures to the target features.

14. A method, comprising:
directing a measurement area of a metrology tool over an approximate first location of a surface of a substrate of an optical device;
identifying a precise location of a first target feature of the optical device, the optical device comprising a plurality of structures disposed on the surface, the plurality of structures including one or more target features, wherein the one or more target features are readable by metrology tools and include at least one of:
one or more structures merged together;
one or more structures merged together surrounded by one or more structures that have been removed; or
one or more structures that have been removed having one or more profiles defined by adjacent structures to the target features;
determining one or more of critical dimensions, gaps, pitches, and peripheral distances of at least one of the plurality of structures based on the precise location within the measurement area; and
repeating the steps of directing the measurement area of the metrology tool, identifying a target feature, and determining the one or more of critical dimensions, the gaps, the pitches, and the peripheral distances of at least one of the plurality of structures within the measurement area at one or more subsequent locations.

15. The method of claim 14, wherein the measurement area is less than about 40 micrometers (μm).

16. The method of claim 14, wherein a ratio of the one or more target features to the plurality of structures is between about 1:100,000 and about 1:1,000,000,000.

17. The method of claim 14, wherein the one or more structures merged together include cross, rectangular, square, circular, semicircular, triangular, and/or other patterns readable by the metrology tools.

18. The method of claim 14, wherein the identifying the precise location of the first target feature of the optical device includes using Image Recognition (IR) software with the metrology tools to identify the precise location of the first target feature.

19. The method of claim 14, wherein the metrology tools include a Scanning Electron Microscope (SEM), Critical Dimension Scanning Electron Microscope (CDSEM), or a Transmission Electron Microscope (TEM).

20. The method of claim 14, wherein the determining the one or more of critical dimensions, the gaps, the pitches, and the peripheral distances of at least one of the plurality of structures includes storing instructions with the metrology tools to determine the one or more of critical dimensions, the gaps, the pitches, and the peripheral distances of at least one of the plurality of structures when the metrology tools move to the measurement area relative to the precise location of the first target feature.
